(19) United States
(12) Patent Application Publication
(10) Pub. No.: US 2009/0097675 A1
(43) Pub. Date: Apr. 16, 2009

(54) SOUND PROVIDING SYSTEM

(75) Inventors: Tadao Kikumoto, Hamamatsu City (JP); Tadashi Nakayama, Hamamatsu City (JP); Mitsuhiro Umeta, Hamamatsu City (JP)

Correspondence Address: KONRAD RAYNES & VICTOR, LLP, 315 S. BEVERLY DRIVE, # 210, BEVERLY HILLS, CA, 90212, US

(73) Assignee: ROLAND CORPORATION, Hamamatsu-city (JP)

(21) Appl. No.: 12/252,315

(22) Filed: Oct. 15, 2008

(30) Foreign Application Priority Data
Oct. 16, 2007 (JP) 2007-269021

(51) Int. Cl. H03G 3/00

(52) U.S. Cl. 381/107

(57) ABSTRACT

A performance sound supplying system includes a plurality of performer amplifiers that are disposed adjacent to performers of musical instruments positioned at different locations on a stage and reproduces supplied performance sound signals as sounds. Plural performance sound signals provided by the guitar, the keyboard, the base and the drum set performed by the performers are supplied to the mixer. A mixer is provided to render a sound volume balance adjustment on each of the supplied performance sound signals based on operations of an operator located on the audience seat side, and supplies the performance sound signals to the performer amplifiers corresponding to the performance sound signals. The mixer also supplies, based on operations by the operator, at least one of the performance sound signals to a non-corresponding performer amplifier among the performer amplifiers.

### CROSS-REFERENCE TO RELATED FOREIGN APPLICATION

This application is a non-provisional application that claims priority benefits under Title 35, Unites States Code, Section 119(a)-(d) from Japanese Patent Application entitled “SOUND PROVIDING SYSTEM” by Tadao Kikumoto, Tadashi Nakayama, and Mitsuhiro Umeta, having Japanese Patent Application Serial No. JP2007-269021, filed on Oct. 16, 2007, which application is incorporated herein by reference in its entirety.

### BACKGROUND

1. Technical Field

Embodiments of the present invention generally relate to performance sound supplying systems in which sounds of a plurality of musical instruments performed, for example, on the stage are supplied to performers' amplifiers placed according to the musical instruments, respectively.

2. Related Art

When electric musical instruments, such as, electric guitars, electric bases, and the like, and electronic musical instruments, such as, synthesizers, electronic drums and the like are performed, performance sound signals outputted from these musical instruments may be amplified by amplifiers and outputted as sounds from speaker systems. So-called performer amplifiers, which combine an amplifier and a speaker system as a unit, such as, guitar amplifiers, base amplifiers, keyboard amplifiers, drum amplifiers and the like are sold.

In a small scale concert, performers may place their performer amplifiers nearby, performance sound signals generated through their performance are supplied to the corresponding performer amplifiers, and performance sounds are outputted through their performer amplifiers, respectively. The sound volume of each of the performer amplifiers may be set by the performer who uses the performer amplifier, through operating the sound volume adjusting controller provided at the performer amplifier. For controlling the balance of sound volumes of the musical instruments, someone stationed on the audience seat side directs each of the performers as to an appropriate sound volume, and each of the performers operates the sound volume adjusting controller according to the direction, thereby adjusting the sound volume of the sound that is generated by the performer amplifier.

On the other hand, in a concert of a larger scale, a mixing system which is described, for example, in paragraphs 0002 and 0003 of Japanese Laid-open Patent Application 2002-320299 may be used. In this case, performance sound signals outputted from each of the musical instruments are supplied to a mixing console disposed on the audience seat side, the signals are appropriately mixed, amplified by the amplifier, and outputted as sounds from the speakers provided on both sides of the stage.

According to the technology that uses performer amplifiers described above, each performer needs to adjust the sound volume of the performer amplifier according to the direction by the person on the audience seat side, and therefore the work for adjusting the sound volume balance may be complex and uncertain. Also, according to the technology that uses a mixing console, the audience hears sounds outputted from locations different from the performers' positions, such that the audience hears sounds with unnatural sound image localization.

### SUMMARY

In accordance with an advantage of some aspects of the invention, there is provided a performance sound supplying system in which performing positions of performers and auditory directions of their performing sounds are in agreement thereby providing natural sound image localizations, and adjustment therefore can be centrally conducted. In addition, in accordance with another aspect of the invention, the performance sound supplying system is capable of outputting each of the performance sounds from any of the other unassociated performer amplifiers, such that the overall sound reproduction capability of the performer amplifiers can be improved and a broad sound image can be created.

In accordance with an embodiment of the invention, a performance sound supplying system includes performer amplifiers. The performer amplifiers are disposed adjacent to performers of musical instruments positioned at different locations on the stage, at places corresponding to the musical instruments being played by the musical instrument performers, respectively, and reproduce supplied performance sound signals as sounds. For example, each of the performer amplifiers may be formed from an amplifier and a speaker. Plural performance sound signals provided by the respective musical instruments performed by the performers are supplied to a mixer. The mixer supplies the performance sound signals to the performer amplifiers corresponding to the musical instruments that provided the performance sound signals. The mixer has a sound volume balance adjusting function. The mixer is capable of supplying at least one of the supplied performance sound signals to any non-corresponding one of the performer amplifiers.

According to the performance sound supplying system thus composed, performance sound signals from the respective musical instruments are collected to the mixer provided at a single location, and after adjusting the balance of sound volumes of performance sounds, the sound signals are supplied to the corresponding performer amplifiers, respectively. Accordingly, the positions where the musical instruments are performed and the auditory directions in which the sounds of the musical instruments can be heard agree with one another, which create natural sound image localizations. Furthermore, the adjustment of sound volume balance can be centrally performed on the side of the mixer such that setup for the adjustment can be securely and readily performed. Moreover, performance sounds can also be outputted from non-corresponding ones of the performer amplifiers. Therefore, for example, when one of the performer amplifiers does not have sufficiently high capability of reproducing specific frequency components, such insufficient reproduction capability can be supplemented by the reproduction capability of the other performer amplifiers whereby the overall reproduction capability of the performer amplifiers can be increased, and a broad sound image can be created by sound reproduction in multi-channels.

The mixer may be provided on the stage side. In this case, a controller may be provided at a location removed from the stage. The controller may be equipped with an operation panel for setting allocation of each of the performance sound signals to each of the performer amplifiers. Based on operations by an operator on the operation panel, each of the performance sound signals may be allocated to any one of the performer amplifiers.

With such a structure, the performance sound signals only need to be supplied to the mixer that is provided on the stage side, such that cables for transmitting the performance sound signals do not need to be installed to the audience seat side.

Alternatively, a plurality of monitor devices may be disposed adjacent to the musical instrument performers corresponding to the musical instruments to be performed by the musical instrument performers. Each of the monitor devices may be composed in a manner to reproduce supplied performance sound signals as sounds, and may be equipped with an operation panel for adjusting the sound volume balance of each of the musical instruments. Each of the monitor devices may output a sound volume balance control signal that designates a balance of sound volumes of the musical instruments designated by the operation panel. Corresponding to each of the monitor devices, the mixer adjusts the sound volume valance of performance sound signals provided from the respective musical instruments according to each of the sound volume balance control signals supplied from the corresponding monitor devices and then mixes the adjusted performance sound signals, respectively, thereby generating a plurality of performance sound signals, whereby the mixer provides the mixed performance sound signal corresponding to each of the monitor devices.

According to such a structure, the monitor devices are provided independently of the mixer, corresponding to the musical instrument performers, respectively, such that a mixed output signal of the performance sound signals whose sound volume balance is adjusted exclusively for each of the performer's monitor devices can be outputted to each of the monitor devices, respectively, and each of the performers can hear the performance sounds in their desired sound volume balance.

The mixer may be capable of supplying at least one performance sound signal to one of the performer amplifiers, and a low frequency component of the at least one performance sound signal to at least another performer amplifier among the performer amplifiers described above. The at least another performer amplifier may be, for example, a performer amplifier having a high capability of reproducing lower frequency sounds. Alternatively, as the at least another performer amplifier, a plurality of performer amplifiers may be used. Even when each performer amplifier to which a performance sound signal is supplied does not have a sufficient capability of reproducing lower frequency sounds, the structure described above makes sufficient lower frequency sound reproduction possible.

At least one of the performance sound signals may be formed from multi-channel signals. For example, when stereo performance sound signals are outputted from one electric or electronic musical instrument, or when performance sound signals of multiple parts are outputted from one electric or electronic musical instrument, the performance sound signals are multi-channel signals. The mixer may supply at least one channel signal of the multi-channel performance sound signals to at least one of the performer amplifiers, and another channel signal of the multi-channel performance sound signals to at least another performer amplifier among the performer amplifiers. With such a structure, the sound outputs in multi-channels can reproduce performance sounds with a broad sound image.

Alternatively, the mixer may be composed to generate effect sound signals in multi-channels based on at least one performance sound signal. Multi-channel effect sound signals may be created by adding effects, for example, reverberations to the performance sound signal in multi-channels. The effect sound signal in one channel among the multi-channel performance sound signals may be supplied to at least one of the performer amplifiers, and the effect sound signal in the other channel may be supplied to at least another performer amplifier among the performer amplifiers. With such a structure, the multi-channel signals added with the effects are outputted as sounds from the plurality of performer amplifiers, such that performance sounds in multi-channels can be reproduced with a broad sound image.

According to the embodiments of the invention, performance of musical instruments on the stage can be presented with natural sound image localizations. Also, adjustments to optimize the balance of sound volumes among musical instruments can be centrally conducted, overall sound reproduction capability of performer amplifiers can be increased, and a broad sound image can be created.

### BRIEF DESCRIPTION OF THE DRAWINGS

FIG. 1 is a block diagram of a performance sound supply system in accordance with a first embodiment of the invention.

FIGS. 2A and 2B are setting screens of the performance sound supplying system shown in FIG. 1.

FIG. 3 is a block diagram of a mixer shown in FIG. 1.

FIG. 4 is a block diagram showing processing contents that are performed by the mixer in FIG. 1 according to a setting shown in FIG. 2A.

FIG. 5 is a block diagram showing a portion of processing contents that are performed by a mixer in accordance with a second embodiment of the invention.

FIG. 6 is a block diagram of a performance sound supply system in accordance with a third embodiment of the invention.

FIG. 7 is a block diagram showing a portion of processing contents that are performed by a mixer of the performance sound supplying system in FIG. 6 according to a setting at a monitor device.

### DESCRIPTION OF EXEMPLARY EMBODIMENTS

A performance sound supplying system in accordance with a first preferred embodiment of the invention may be used when multiple performers (for example, four performers) perform a plurality of electric or electronic musical instruments, for example, an electric guitar 2, a keyboard 4, an electric base 6 and an electronic drum set 8.

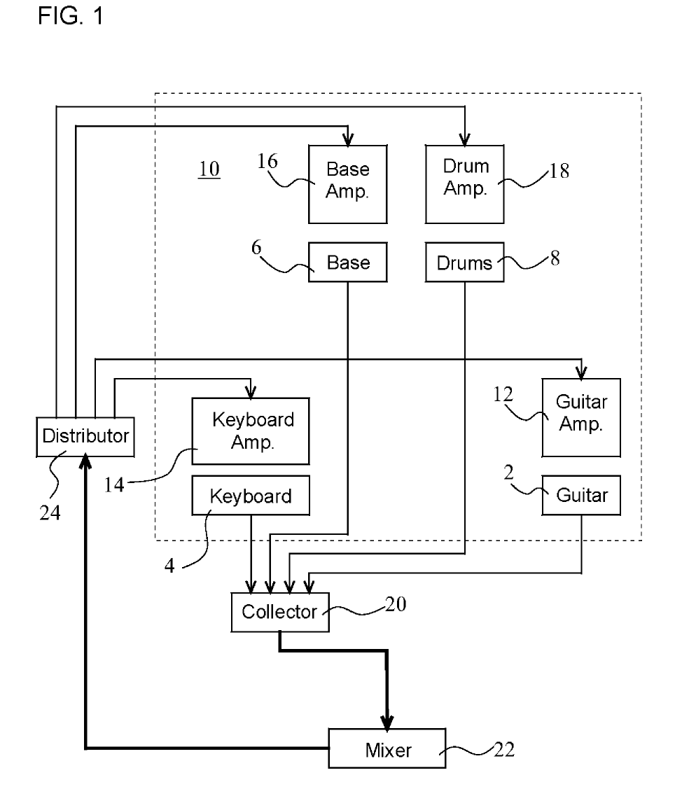

As shown in FIG. 1, the electric guitar 2, the keyboard 4, the electric base 6 and the electronic drum set 8 that are to be performed by performers are disposed at mutually different positions on the stage 10. Performer amplifiers corresponding to these musical instruments, for example, a guitar amplifier 12, a keyboard amplifier 14, a base amplifier 16 and a drum amplifier 18 are disposed adjacent to these musical instruments, respectively. The guitar amplifier 12, the keyboard amplifier 14, the base amplifier 16 and the drum amplifier 18 are oriented to output their respective sounds toward the audience seats.

Performance sound signals generated through performance by the performers of the electric guitar 2, the keyboard 4, the electric base 6 and the electronic drum set 8 are collected to a collector device 20 disposed at the side of the stage 10. The performance sound signals collected by the collector device 20 are supplied to a mixer 22 that is disposed among the audience seats removed from the stage 10.

The mixer 22, in response to operations of an operator of the mixer 22, may adjust the sound volume balance of performance sound signals, mix performance sound signals, change their frequency characteristics, and add effects, such as for example, reverberations to performance sound signals, and supplies mixer output signals in a number equal to the total number of the performer amplifiers including the guitar amplifier 12, the keyboard amplifier 14, the base amplifier 16 and the drum amplifier 18 to a distributor device 24 disposed at the side of the stage 10. The distributor device 24 supplies the mixer output signals to the guitar amplifier 12, the keyboard amplifier 14, the base amplifier 16 and the drum amplifier 18, respectively. It is noted that a plurality of performance sound signals are transmitted between the collector device 20 and the mixer 22, and a plurality of mixer output signals are also transmitted between the mixer 22 and the distributor device 24.

For transmission of these signals, cables in a number equal to the number of performance sound signals, or a multi-cable that binds cables in a number equal to the number of the mixer output signals may be used. Alternatively, the performance sound signals and the mixer output signals may be multiplexed by time-division or packetting, and transmitted through single cables, respectively. In the case of multiplexing by time-division or packetting, the signal transmission needs to be in a digital format. On the other hand, the signal transmission through multiple cables may be conducted in a digital format or an analog format.

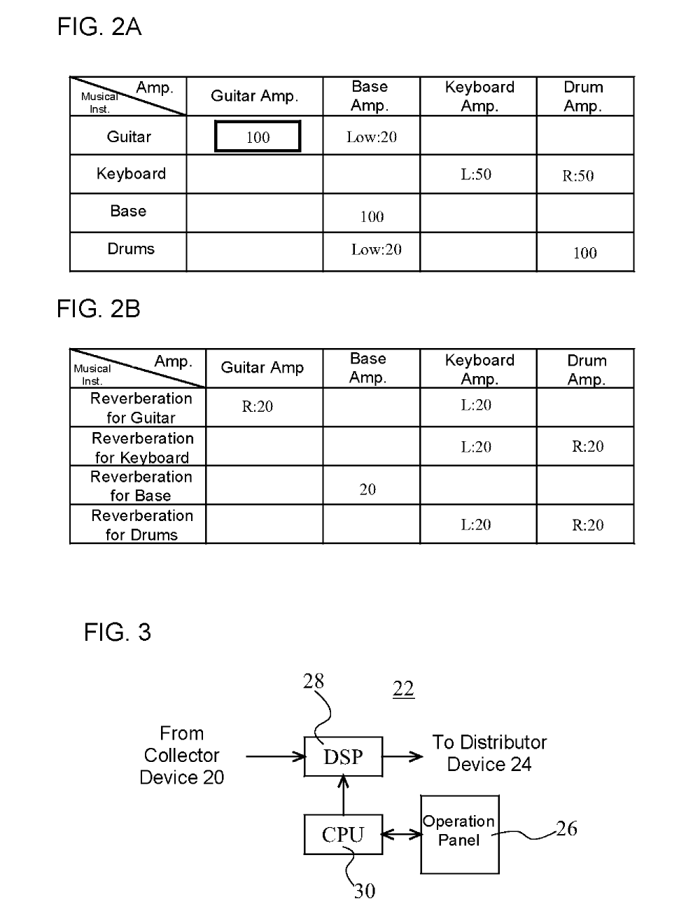

The mixer 22 has an operation panel 26 (see FIG. 3). The operation panel 26 is equipped with a display device that displays setting screens. By operating the setting screens displayed on the display device, a variety of parameters can be set. FIGS. 2A and 2B show examples of the setting screens.

As shown in FIGS. 2A and 2B, the setting screens may be displayed in tables, wherein each of the rows represents each of the musical instruments, and each of the columns represents each of the performer amplifiers. The display device may be formed from a touch panel, and by depressing intersecting areas between the rows and the columns on the touch panel, set contents corresponding to the depressed intersections are placed in editable states. An area in an editable state is indicated with a frame (see an intersection area between the guitar and the guitar amplifier in FIG. 2A). When the operator of the mixer wants to supply performance sound signals of a certain musical instrument to a specified one of the performer amplifiers, the operator touches the panel in an intersecting area between a row corresponding to the musical instrument and a column corresponding to the specified performer amplifier. Then the operator operates operation elements (not shown) provided on the operation panel 26, thereby setting the level of performance sound signals to be supplied to the performer amplifier, frequency characteristics of the performance sound signals to be supplied, and the like. Also, the operator of the mixer 22 may set as to what level of reverberation is to be added to the performance sound signal of each of the musical instruments to which of the performer amplifiers.

FIG. 2A shows a setting screen for setting as to how the performance sound signal of each of the musical instruments is to be allocated to each of the performer amplifiers. In this example, the performance sound signal from the guitar 2 is supplied to the guitar amplifier 12 at a level of 100, and its lower-frequency components are supplied to the base amplifier 16 at a level of 20. Similarly, among multi-channel signals from the keyboard 4, for example, among L and R stereo performance sound signals, the L signal is supplied to the keyboard amplifier 14 at a level of 50, and the R signal is supplied to the drum amplifier 18 at a level of 50. The performance sound signal from the base 6 is supplied to the base amplifier 16 at a level of 100. The performance sound signal from the drum set 8 is supplied to the drum amplifier 18 at a level of 100, and its lower frequency components are supplied to the base amplifier at a level of 20.

It is clear from the setting described above that the performance sound signal of each of the musical instruments is supplied to the corresponding performer amplifier. Accordingly, the performance of each of the musical instruments on the stage is presented with a natural sound image localization. Also, the levels of sound volumes at the performer amplifiers corresponding to the performance sound signals of the respective musical instruments may be adjusted to adjust the balance of their sound volumes. Such adjustment can be centrally conducted at the mixer provided on the audience seat side. Also, lower frequency components of the performance sound signals of the guitar 2 and the drum set 8 are supplied to the base amplifier 16 that has ample low frequency component reproducing capability. By supplying low frequency components to the base amplifier 6, when the guitar amplifier 12 and the drum amplifier 18 may not have sufficient low frequency component reproducing capability, lower frequency components can be sufficiently reproduced. Lower frequency components of the performance sounds of the guitar 2 and the drum set 8 are reproduced from the base amplifier 16, which is different from the corresponding guitar amplifier 12 and the drum amplifier 18. However, the human's auditory sense is relatively insensitive to sound image localization with respect to low frequency components, and therefore the overall sound image localization would not be damaged. Moreover, the performance sounds of the keyboard 4 whose performance sound signal is in a stereo format are reproduced by separate performer amplifiers (by the keyboard amplifier 14 and the drum amplifier 18), such that the sounds can be reproduced in a broad sound stage.

FIG. 2B shows a screen for setting as to how reverberation signals for adding reverberation components to the performance sound signals provided from the musical instruments are to be allocated to the respective performer amplifiers. The mixer is capable of generating multi-channel reverberation components, for example, stereo reverberation components for each of the performance signals of the musical instruments except the base 6, and is capable of generating monaural reverberation components for the base 6. The mixer is also capable of selectively supplying the reverberation components to the performer amplifiers. In the example shown in FIG. 2B, L-channel signal of the reverberation components for the guitar 2 is supplied to the keyboard amplifier 14 at a level of 20, and R-channel signal of the reverberation components for the guitar 2 is supplied to the guitar amplifier 12 at a level of 20. L-channel signal of the reverberation components for the keyboard 4 is supplied to the keyboard amplifier 14 at a level of 20, and R-channel signal of the reverberation components for the keyboard 4 is supplied to the drum amplifier 18 at a level of 20. The reverberation components for the base 6 are supplied to the base amplifier 16. L-channel signal of the reverberation components for the drum 8 is supplied to the keyboard amplifier 14 at a level of 20, and R-channel signal of the reverberation components for the drum 8 is supplied to the drum amplifier 18 at a level of 20. In this manner, the reverberation components are supplied to the corresponding performer amplifiers, respectively, and also supplied to those of the performer amplifiers other than the corresponding performer amplifiers. As a result, a broad sound image can be created.

FIG. 3 schematically shows the structure of the mixer 22. The mixer 22 may include a DSP 28 and a CPU 30. Performance sound signals provided by the collector device 20 are inputted in the DSP 28 of the mixer 22. The DSP 28 renders various processing to each of the inputted performance sound signals, such as, sound level control, frequency characteristic control, addition of reverberation and signal mixing; generates mixer output signals for the respective performer amplifiers; and supplies the mixer output signals to the distributor device 24. The CPU 30 displays setting contents set by the operation panel 26 on the display of the operation panel 26, and controls signal processing contents to be rendered by the DSP 28 according to the setting contents.

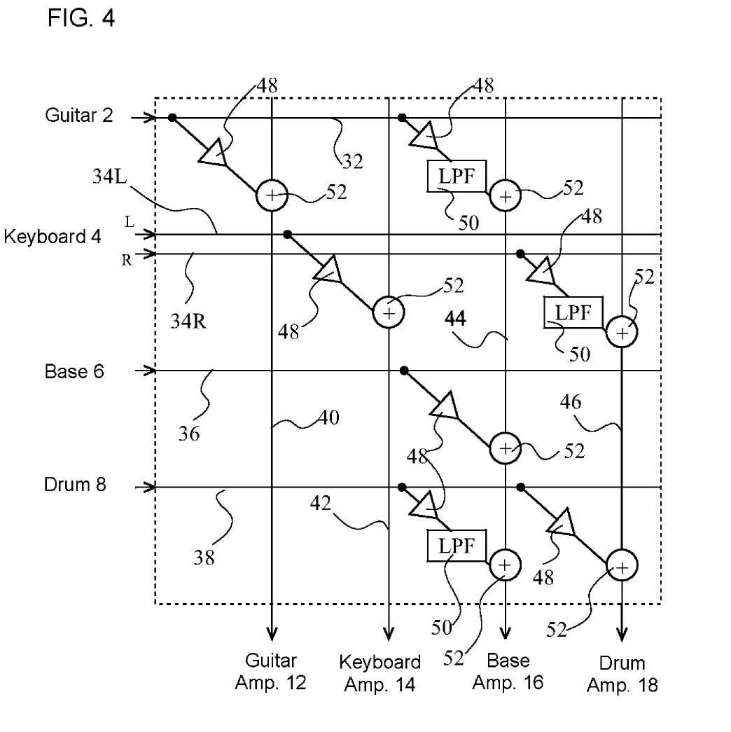

FIG. 4 is a block diagram showing processing contents of the DSP 28 according to the setting shown in FIG. 2A. Performance sound signals from the guitar 2, the keyboard 4, the base 6 and the drum set 8 are inputted in their corresponding input channels 32, 34R, 34L, 36 and 38, respectively. Output channels 40, 42, 44 and 46 to the guitar amplifier 12, the keyboard amplifier 14, the base amplifier 16 and the drum amplifier 18 are disposed in a manner to traverse the input channels, and mixer output signals are outputted from the output channels 40, 42, 44 and 46 to the corresponding performer amplifiers. The DSP 28 includes level controlling devices 48 for controlling the levels of the inputted performance sound signals and low pass filters 50 that pass low frequency components of the inputted performance sound signals. Performance sound signals are supplied to the level controlling devices 48 from their corresponding input channels, respectively, and the performance sound signals that are level-controlled by the level controlling devices 48 are supplied to the low pass filters 50, respectively. Output signals from the level controlling devices 48 or the low pass filters 50 are supplied through adders 52 to the corresponding output channels, respectively. Level adjustment by the level controlling devices 48 is performed based on level control signals given according to operations of the operation elements of the operation panel 26, and cutoff frequencies of the low pass filters 50 are set based on characteristic control signals given according to operations of the operation elements of the operation panel 26.

Upon changing the settings at the operation panel 26, the processing contents by the DSP 28 are changed according to the changed setting contents, whereby the arrangement positions and number of the level controlling devices 48 and the low pass filters 50, the values of the level controlling signals, and the values of the characteristic controlling signals are changed.

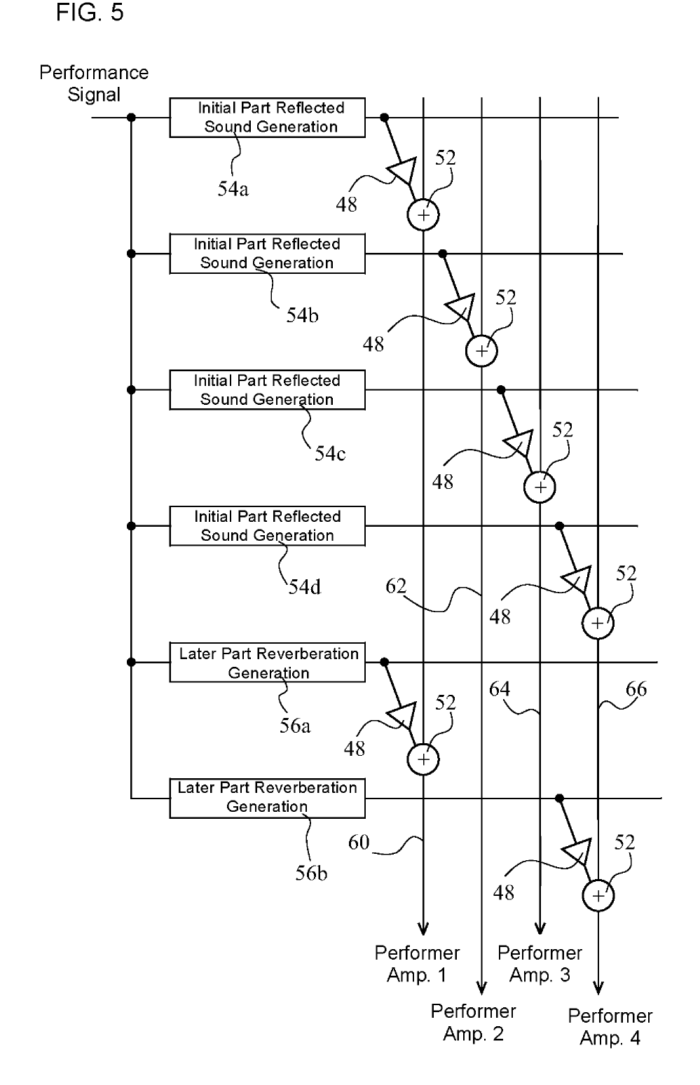

FIG. 5 is a block diagram showing processing contents for generating reverberation components to be added by the DSP 28 in a performance sound supplying system in accordance with a second embodiment of the invention. In this embodiment, plural kinds of reverberation components are generated from one performance sound signal. Other structural components are generally the same as those of the first embodiment, and therefore their detailed description is omitted. As the reverberation components, four kinds of initial part reflected sound components and two kinds of later part reverberation components are generated. A performance sound signal is supplied to four initial part reflected sound generation sections 54a, 54b, 54c and 54d, and two later part reverberation generation sections 56a and 56b. The initial part reflected sound generation sections 54a, 54b, 54c and 54d are set such that initial part reflected sounds to be generated by the initial part reflected sound generation sections 54a, 54b, 54c and 54d have mutually different delay times. The later part reverberation generation sections 56a and 56b are set such that later part reverberations to be generated by the later part reverberation generation sections 56a and 56b have mutually different delay times and different reverberation decay times.

The initial part reflected sound component of the initial part reflected sound generation section 54a and the later part reverberation component of the later part reverberation generation section 56a are supplied through the level adjusting devices 48 and the adders 52, respectively, to an output channel 60, and then supplied to an appropriate performer amplifier 1 among the guitar amplifier 12, the keyboard amplifier 14, the base amplifier 16 and the drum amplifier 18. The initial part reflected sound component of the initial part reflected sound generation section 54b is supplied through the level adjusting device 48 and the adder 52 to an output channel 62, and then supplied to a performer amplifier 2 different from the first performer amplifier 1 among the amplifiers described above. The initial part reflected sound component of the initial part reflected sound generation section 54c is also supplied through the level adjusting device 48 and the adder 52 to an output channel 64, and then supplied to a performer amplifier 3 different from the first and second performer amplifiers 1 and 2 among the amplifiers described above. The initial part reflected sound component of the initial part reflected sound generation section 54d and the later part reverberation component of the later part reverberation generation section 56b are supplied through the level adjusting devices 48 and the adders 52, respectively, to an output channel 66, and then supplied to a performer amplifier 4 different from the first, second and third performer amplifiers 1, 2 and 3 among the amplifiers described above.

By supplying the reverberation components to different performer amplifiers according to the kinds of reverberation components, reverberations with a broad sound image can be obtained. It is noted that, in the present embodiment, multiple reverberation components for a single performance sound signal are described. It is noted that multi-channel reverberation components can be similarly generated and reproduced for each of the other performance sound signals.

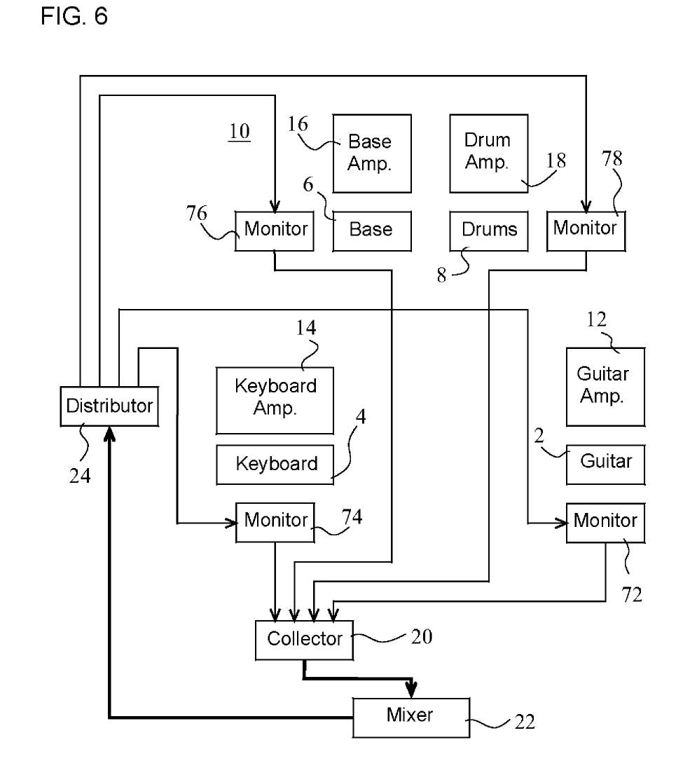

FIG. 6 shows a third embodiment of the invention. The third embodiment uses a monitor system introduced in the first embodiment, which allows performers to monitor performance sounds, independently of sounds outputted from the performer amplifiers. Components that are the same as those of the first embodiment are referenced with the same reference numerals and their description is omitted. Also, signal paths that are the same as those of the first embodiment are omitted in FIG. 6.

Monitor devices 72, 74, 76 and 78 are disposed adjacent to the performers, respectively. Each of the monitor devices 72, 74, 76 and 78 may be provided with an operation panel, an amplifier for reproducing monitor output signals supplied from a mixer 22 as sounds, and a headphone and/or a speaker system. The operation panel is used by the performer to adjust the sound volume balance of performance sounds of the musical instruments included in monitor output signals that are supplied from the mixer 22 to the corresponding monitor device. When the monitor device is provided with a speaker system, the monitor device may be oriented such that sounds from the speaker system of the monitor device are outputted toward the performer, not toward the audience seats. For example, the monitor device 72 outputs a sound volume balance control signal that designates the balance of sound volumes of those of the musical instruments designated by the operation panel. The other monitor devices 74, 76 and 78 also independently output sound volume balance control signals, each of which designates the balance of sound volumes of those of the musical instruments designated by each of the operation panels of the respective monitor devices 74, 76 and 78. The sound volume balance control signals from the monitor devices 72, 74, 76 and 78 are collected at the collector device 20, and supplied from the collector device 20 to the mixer 22. The mixer 22 mixes performance sound signals from the respective musical instruments, according to each of the sound volume balance control signals, exclusively for each of the corresponding monitor devices 72, 74, 76 and 78, and generates monitor output signals exclusively for the monitor devices 72, 74, 76 and 78, respectively. In this instance, the balance of sound volumes of the musical instruments in each of the monitor output signals of the monitor devices 72, 74, 76 and 78 may be made different from one another. The generated monitor output signals for the monitor devices 72, 74, 76 and 78 are supplied through the distributor device 24 to the monitor devices 72, 74, 76 and 78, respectively.

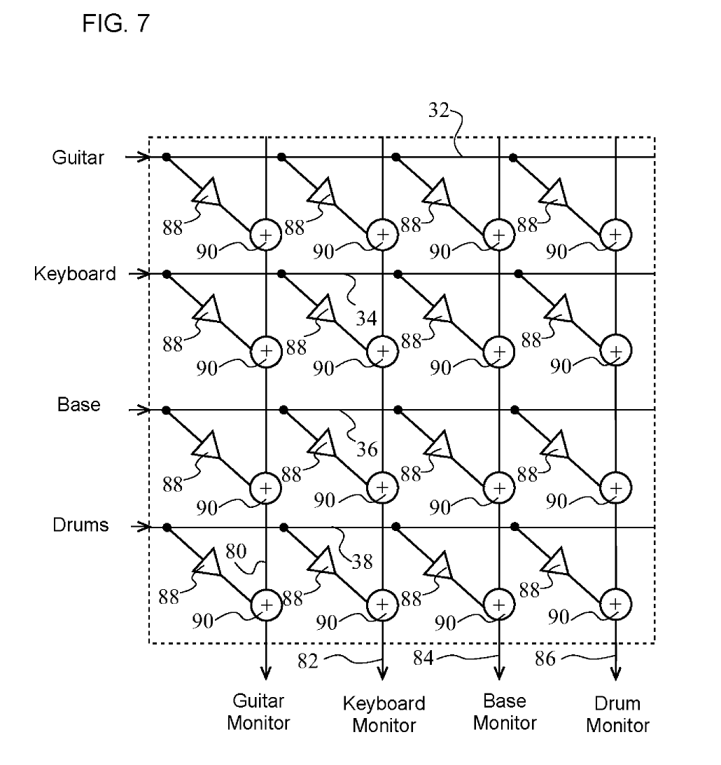

FIG. 7 shows processing for generating monitor output signals for the respective monitor devices performed by the mixer 22. Performance sound signals from the musical instruments are supplied to corresponding input channels 32, 34, 36 and 38, respectively. Each of the input channels 32, 34, 36 and 38 is connected to each of monitor output channels 80, 82, 84 and 86 corresponding to the monitor devices 72, 74, 76 and 78, respectively, through a level adjusting device 88 and an adder 90. Level adjustment by each of the level adjusting devices 88 is performed according to the sound volume balance control signal supplied from each of the monitor devices 72, 74, 76 and 78, respectively, and the performance sounds signals are mixed by each of the adders 90.

With the structure described above, for example, the monitor device 72 for the guitar can reproduce sounds of the mixed performance sound signals so that the performance sounds that are mixed with a sound volume valance desired by the guitar performer can be monitored. At each of the other monitor devices 74, 76 and 78, performance sound signals that are mixed with a sound volume valance desired by each of the performers positioned nearby can also be monitored.

In the embodiment described above, performance sound signals from the respective musical instruments are supplied to the mixer without passing through performer amplifiers. However, performance sound signals from the respective musical instruments may be supplied to the mixer through performer amplifiers corresponding to the respective musical instruments. Generally, a performer amplifier is equipped with various functions, such as, a function to adjust the tone quality and the distortion of sounds to be outputted, and the performer can adjust the tone quality and the distortion of sounds by operating the operation elements provided on the performer amplifier according to the performer's preference. In accordance with the embodiment of the invention, performance sound signals from musical instruments may be supplied to the performer amplifiers, and the performance sound signals whose levels of tone quality and distortion are adjusted by the performer amplifiers may be supplied to the mixer, whereby the preference of the performer can be reflected on the performance sounds to be outputted. In this case, the performer amplifiers do not directly output sounds of the performance sound signals supplied from the musical instruments, and mixer signals supplied from the mixer are outputted as sounds. The performer amplifier may preferably be capable of switching between a sound output mode of directly outputting the performance sound signals provided from the musical instrument like an ordinary performer amplifier of related art and the sound output mode according to the embodiment described above. When the performer adjusts the tone quality and distortion, the same sound output mode as that of the related art performer amplifier may be used such that the adjustment can be conducted without using the mixer, and the sound output mode according to the embodiment described above may be used after the adjustment.

In accordance with the embodiments described above, the collector device 20 and the distributor device 24 are described as independent devices, but may be contained in a single casing. Also, in accordance with the embodiments described above, performance sound signals are processed such that performance sounds are distributed to each of the performer amplifiers by the mixer disposed on the audience seat side. However, the mixer 22 may be disposed on the stage side, and a controller for controlling the mixer 22 may be disposed on the audience seat side. In this case, the controller may be provided with an operation panel similar to that of the mixer 22, and control signals representative of contents set by the operation panel may be transmitted from the controller to the mixer 22. The mixer 22 processes the performance sound signals based on the control signals supplied from the controller, which are then supplied to the distributor device 24. Also, the collector device 20, the mixer 22 and the distributor device 24 may be housed in a single casing.

In the embodiments described above, the base amplifier 16 that has a high capability of reproducing lower frequency components is used in order to reproduce ample lower sounds. However, instead of the base amplifier 16, a dedicated amplifier equipped with a sub-woofer that outputs sounds with only low frequency components may be used. Alternatively, a plurality of performer amplifiers with an ordinary level of lower frequency component reproducing capability may be used. Even when each of the performer amplifiers does not have a high reproduction capability of reproducing lower frequency components, their lower frequency reproduction capability can be improved by using the plurality of performer amplifiers.

In accordance with the first embodiment, an example in which two channel signals in stereo mode are supplied to individual performer amplifiers in order to obtain a broad sound image is described, using the keyboard 4 as an example. However, the present invention is also applicable to other embodiments, for example, to cases other than the stereo mode, to cases with three channels or more, and the like. Also, when performance sound signals of a plurality of parts are outputted from a single musical instrument, signals of the respective parts may be supplied to independent performer amplifiers, respectively. For example, the keyboard 4 may have a capability of reproducing performance sound signals of different tone colors independently for the right hand part and the left hand part, and the performance sound signal for the right hand part and the performance sound signal for the left hand part may be supplied to independent performer amplifiers, whereby stereophonic sounds can be obtained. Also, when the performer moves on the stage during performance, performance sound signals generated by the performer may be supplied to any of the performer amplifiers on the stage closest to the performer in movements, such that the sound image moves according to the movements of the performer. Alternately, when performance sound signals are supplied to a plurality of performer amplifiers, the level and phase of the performance sound signal to be supplied to each of the performer amplifiers may be controlled, thereby changing the position of the sound image.

In accordance with the first and second embodiments, as an example of effects obtained when components of effect sounds to be added to musical notes are supplied to a plurality of performer amplifiers, reverberation components are described. Without being limited to this example, components of chorus effect or the like may be supplied to a plurality of performer amplifiers. In each of the embodiments described above, examples of handling performance sound signals outputted from electric musical instruments and electronic musical instruments are described. However, without being limited to these examples, the present invention may be carried out, by using musical instrument sounds generated by acoustic musical instruments, such as, for example, acoustic guitars, wind instruments and the like, signals of human's singing voices picked up by a microphone and the like, as performance sound signals.

What is claimed is:

1. A system for supplying performance sounds for performers of musical instruments positioned at different locations on a stage, comprising:
a plurality of performer amplifiers that are disposed adjacent to the performers of the musical instruments positioned at different locations on the stage at places where the musical instruments are performed by the performers, wherein there is at least one of the performer amplifiers corresponding to each of the musical instruments, and wherein the performer amplifiers corresponding to the musical instruments reproduce supplied performance sound signals as sounds; and
a mixer for performing operations, the operations comprising:
receiving performance sound signals provided by the musical instruments performed by the performers;
rendering a sound volume balance adjustment on each of the performance sound signals supplied based on operation of an operator located on an audience seat side to produce adjusted performance sound signals;
supplying the adjusted performance sound signals to the performer amplifiers corresponding to the musical instruments that provided the performance sound signals adjusted to produce the supplied adjusted performance sound signals; and
supplying, based on operation by the operator, at least one of the adjusted performance sound signals to a non-corresponding one of the performer amplifiers that is different from the at least one performer amplifier corresponding to the at least one musical instrument that provided the performance sound signals adjusted to produce the supplied adjusted performance sound signals.

2. The system of claim 1, wherein the mixer is provided on the stage side, and includes a controller provided at a location separated from the stage, wherein the controller is equipped with an operation panel for setting as to which of the performance sound signals are to be allocated to which of the performer amplifiers, and allocates each of the performance sound signals to any of the performer amplifiers based on operation to the operation panel by the operator.

3. The system of claim 1, further comprising:
a plurality of monitor devices disposed adjacent to the performers of the musical instruments corresponding to the musical instruments to be performed by the performers, wherein the monitor devices reproduce the performance sound signals supplied as sounds, and include an operation panel for adjusting balance of sound volumes of the musical instruments, and outputs a sound volume balance control signal that designates the balance of sound volumes of the musical instruments designated by the operation panel;
wherein the mixer further performs:
adjusting the balance of sound volumes of performance sound signals provided from the musical instruments according to the sound volume balance control signals supplied from the corresponding monitor devices;
mixing the adjusted performance sound signals to generate a plurality of mixed performance sound signals; and
providing the mixed performance sound signal to the monitor devices.

4. The system of claim 1, wherein the mixer supplies at least one of the adjusted performance sound signals to one of the performer amplifiers, and a low frequency component of the at least one of the adjusted performance sound signals to at least another performer amplifier among the performer amplifiers.

5. The system of claim 1, wherein at least one of the adjusted performance sound signals is formed from signals in multi-channels, and wherein the mixer further supplies the signal in at least one of the channels of the multi-channel performance sound signals to at least one of the performer amplifiers, and the signal in another of the channels of the multi-channel performance sound signals to at least another performer amplifier among the performer amplifiers.

6. The system of claim 1, wherein the mixer further performs operations comprising:
generating effect sound signals in multi-channels based on at least one of the performance sound signals;
supplying the effect sound signal in one channel among the multi-channel performance sound signals to at least one of the performer amplifiers; and
supplying the effect sound signal in another channel to at least another performer amplifier among the performer amplifiers.

7. The system of claim 1, wherein the mixer further includes level controlling devices for processing performance sound signals from the musical instruments, wherein rendering the sound volume balance adjustment comprises the level controlling devices processing the performance sound signals from the musical instruments to contribute to producing the adjusted performance sound signals.

8. The system of claim 1, wherein the mixer further includes a plurality of reverberation component generation sections for receiving one performance sound signal from one of the musical instruments, wherein the reverberation component generation sections generate the adjusted performance sound signals to supply to the performer amplifier corresponding to the musical instrument that provided the performance sound signal received by the reverberation component generation sections and to supply to the non-corresponding performance amplifier with respect to the musical instrument that provided the performance sound signal received by the reverberation component generation sections.

9. A method, comprising:
providing a plurality of performer amplifiers disposed adjacent to performers of musical instruments positioned at different locations on a stage at places where the musical instruments are performed by the performers, wherein there is at least one of the performer amplifiers corresponding to each of the musical instruments, and wherein the performer amplifiers corresponding to the musical instruments reproduce supplied performance sound signals as sounds;
receiving performance sound signals provided by musical instruments performed by performers;
rendering a sound volume balance adjustment on each of the performance sound signals supplied based on operation of an operator located on an audience seat side to produce adjusted performance sound signals;
supplying the adjusted performance sound signals to the performer amplifiers corresponding to the musical instruments that provided the performance sound signals adjusted to produce the supplied adjusted performance sound signals; and
supplying, based on operation by the operator, at least one of the adjusted performance sound signals to a non-corresponding one of the performer amplifiers that is different from the at least one performer amplifier corresponding to the at least one musical instrument that provided the performance sound signals adjusted to produce the supplied adjusted performance sound signals.

10. The method of claim 9, further comprising:
providing a mixer to performs the operations of receiving the performance sound signals, rendering the sound volume balance adjustment, and supplying the adjusted performance sound signals, wherein the mixer is provided on the stage side, and includes a controller provided at a location separated from the stage, wherein the controller is equipped with an operation panel for setting as to which of the performance sound signals are to be allocated to which of the performer amplifiers, and allocates each of the performance sound signals to any of the performer amplifiers based on operation to the operation panel by the operator.

11. The method of claim 9 further comprising:
providing a plurality of monitor devices disposed adjacent to the performers of the musical instruments corresponding to the musical instruments to be performed by the performers, wherein each of the monitor devices reproduces the performance sound signals supplied as sounds, and is equipped with an operation panel for adjusting balance of sound volumes of the musical instruments; and
outputting, by the monitor devices, a sound volume balance control signal that designates the balance of sound volumes of the musical instruments designated by the operation panel;
adjusting the balance of sound volumes of performance sound signals provided from the musical instruments, according to the sound volume balance control signals supplied from the corresponding monitor devices;
mixing the adjusted performance sound signals to generate a plurality of mixed performance sound signals; and
providing the mixed performance sound signal to the monitor devices.

12. The method of claim 9, further comprising:
supplying at least one of the adjusted performance sound signals to one of the performer amplifiers, and a low frequency component of the at least one of the adjusted performance sound signals to at least another performer amplifier among the performer amplifiers.

13. The method of claim 9, wherein at least one of the adjusted performance sound signals is formed from signals in multi-channels, further comprising:
supplying the signal in at least one of the channels of the multi-channel performance sound signals to at least one of the performer amplifiers, and the signal in another of the channels of the multi-channel performance sound signals to at least another performer amplifier among the performer amplifiers.

14. The method of claim 9, further comprising:
generating effect sound signals in multi-channels based on at least one of the performance sound signals;
supplying the effect sound signal in one channel among the multi-channel performance sound signals to at least one of the performer amplifiers; and
supplying the effect sound signal in another channel to at least another performer amplifier among the performer amplifiers.

15. The method of claim 9, further comprising:
providing level controlling devices for processing performance sound signals from the musical instruments, wherein rendering the sound volume balance adjustment comprises the level controlling devices processing the performance sound signals from the musical instruments to contribute to producing the adjusted performance sound signals.

16. The method of claim 9, further comprising:
providing a plurality of reverberation component generation sections for receiving one performance sound signal from one of the musical instruments, wherein the reverberation component generation sections generate the adjusted performance sound signals to supply to the performer amplifier corresponding to the musical instrument that provided the performance sound signal received by the reverberation component generation sections and to supply to the non-corresponding performance amplifier with respect to the musical instrument that provided the performance sound signal received by the reverberation component generation sections.

17. A mixer in communication with a plurality of performer amplifiers disposed adjacent to performers of musical instruments positioned at different locations on a stage at places where the musical instruments are performed by the performers, wherein there is at least one of the performer amplifiers corresponding to each of the musical instruments, and wherein the performer amplifiers corresponding to the musical instruments reproduce supplied performance sound signals as sounds, wherein the mixer performs operations, the operations comprising:
receiving performance sound signals provided by musical instruments performed by performers;
rendering a sound volume balance adjustment on each of the performance sound signals supplied based on operation of an operator located on an audience seat side to produce adjusted performance sound signals;
supplying the adjusted performance sound signals to the performer amplifiers corresponding to the musical instruments that provided the performance sound signals adjusted to produce the supplied adjusted performance sound signals; and
supplying, based on operation by the operator, at least one of the adjusted performance sound signals to a non-corresponding one of the performer amplifiers that is different from the at least one performer amplifier corresponding to the at least one musical instrument that provided the performance sound signals adjusted to produce the supplied adjusted performance sound signals.

18. The mixer of claim 17, wherein the mixer is provided on the stage side, and includes a controller provided at a location separated from the stage, wherein the controller is equipped with an operation panel for setting as to which of the performance sound signals are to be allocated to which of the performer amplifiers, and allocates each of the performance sound signals to any of the performer amplifiers based on operation to the operation panel by the operator.

19. The mixer of claim 17, wherein the mixer is in communication with a plurality of monitor devices disposed adjacent to the performers of the musical instruments corresponding to the musical instruments to be performed by the performers, wherein each of the monitor devices reproduces the performance sound signals supplied as sounds, is equipped with an operation panel for adjusting balance of sound volumes of the musical instruments, and outputs a sound volume balance control signal that designates the balance of sound volumes of the musical instruments designated by the operation panel, wherein the operations further comprise:
adjusting the balance of sound volumes of performance sound signals provided from the musical instruments, according to the sound volume balance control signals supplied from the corresponding monitor devices;
mixing the adjusted performance sound signals to generate a plurality of mixed performance sound signals; and
providing the mixed performance sound signal to the monitor devices.

20. The mixer of claim 17, wherein the operations further comprise:
supplying at least one of the adjusted performance sound signals to one of the performer amplifiers, and a low frequency component of the at least one of the adjusted performance sound signals to at least another performer amplifier among the performer amplifiers.

21. The mixer of claim 17, wherein at least one of the adjusted performance sound signals is formed from signals in multi-channels, wherein the operations further comprise:
supplying the signal in at least one of the channels of the multi-channel performance sound signals to at least one of the performer amplifiers, and the signal in another of the channels of the multi-channel performance sound signals to at least another performer amplifier among the performer amplifiers.

22. The mixer of claim 17, wherein the operations further comprise:
generating effect sound signals in multi-channels based on at least one of the performance sound signals;
supplying the effect sound signal in one channel among the multi-channel performance sound signals to at least one of the performer amplifiers; and
supplying the effect sound signal in another channel to at least another performer amplifier among the performer amplifiers.

23. The mixer of claim 17, wherein the mixer includes level controlling devices for processing performance sound signals from the musical instruments, wherein rendering the sound volume balance adjustment comprises the level controlling devices processing the performance sound signals from the musical instruments to contribute to producing the adjusted performance sound signals.

24. The mixer of claim 17, wherein the mixer includes a plurality of reverberation component generation sections for receiving one performance sound signal from one of the musical instruments, wherein the reverberation component generation sections generate the adjusted performance sound signals to supply to the performer amplifier corresponding to the musical instrument that provided the performance sound signal received by the reverberation component generation sections and to supply to the non-corresponding performance amplifier with respect to the musical instrument that provided the performance sound signal received by the reverberation component generation sections.
